(19) United States
(12) Patent Application Publication
(10) Pub. No.: US 2012/0010836 A1
(43) Pub. Date: Jan. 12, 2012

(54) ELECTROMAGNETIC RADIATION MAPPING SYSTEM

(75) Inventors: Aldo Shemesh, Rehovot (IL); Ilan Koren, Rehovot (IL)

(73) Assignee: Yeda Research and Development Co. Ltd, Rehovot (IL)

(21) Appl. No.: 13/143,209

(22) PCT Filed: Jan. 3, 2010
(86) PCT No.: PCT/IL10/00003

§ 371 Date: Sep. 22, 2011

Related U.S. Application Data
(60) Provisional application No. 61/193,878, filed on Jan. 5, 2009.

(51) Int. Cl. G01R 29/08

(52) U.S. Cl. 702/76

(57) ABSTRACT

Apparatus for radiation mapping of a region comprises a spectrum analyzer for analyzing a local radiation field according to wavelength, and a positioning unit for obtaining a position reading to correlate with said local radiation field, thereby to provide said radiation mapping. The results may be provided as layers to a map, and different layers may be provided for different frequencies and different times of the day.

### FIELD AND BACKGROUND OF THE INVENTION

The present invention, in some embodiments thereof, relates to a radiation mapping system, method and device and, more particularly, but not exclusively, to such a system, method and device for measuring radiation pollution in the urban environment. In particular the present embodiments provide a system that is sensitive to highly localized changes in the radiation field, such highly localized changes being typical of cellular radiation in the urban environment.

The present teaching particularly questions the way in which the cellular radiation field is measured in order to estimate any hazards resulting therefrom. The current art measures the mean energy loading in order to assess risk levels. That is to say the current art uses a broadband power detection system to obtain the overall power due to radiation over a broad frequency range.

It is not well understood yet in what way and how the biological tissue reacts to the presence of electromagnetic (EM) radiation and what are the most important statistical parameters to use in order to estimate the risk. There are a number of hypotheses for the way in which radiation may affect a biological cell exposed thereto. Theoretically, it is not clear if the probability of a biological cell being modified is high when the average EM field is high, or when sudden changes in the field occur, or whether the probability may correlate with the maximum field values, typically occurring for relatively short times, that are many orders of magnitudes higher than the average. Furthermore it is not clear whether the probability is frequency related, that is to say the biological cell may be highly sensitive to certain frequencies and not others, so that a certain peak or average value at one frequency may be more harmful than a much higher peak or average value at another frequency.

Electromagnetic radiation, especially in the spectrum bands used by cellular phones, is one of the main environmental pollutants of the world. It is expected to dramatically increase during the next decade due to the ever-growing demand for cellular communication and services. The demand is currently being met by increasing numbers of antennas in urban and rural environments, and by increasing the output of existing antennas. Regulation generally limits the overall average radiation level, so antennas are being used with ever more efficient algorithms to make more use of the available spectrum within the overall power limitations.

During the past few years, several studies have demonstrated the serious potential of health hazards due to exposure to cell phone radiation. The number of health related publications increase every year, pointing to the fact that there is a growing public concern with no clear answers. A European study, published in January 2007, focused on tumors in a population of 1500 people. It concluded that “a statistically significant increase in the incidence of tumors on the side of the head where the users hold their cell phones” can be established in 5 European countries for people that have used a cellular phone for over 10 years. The full data-base for another 11 countries will have been completed in the future. Another study published in Sweden discovered that incidence of brain tumors in rural areas of Sweden was much higher among users of GSM cell phones than among rural residents who were not cell phone users. The fact that some studies have found a correlation between cell phone use and adverse health problems whereas some have not, suggests that much more research is required in order to establish a firm conclusion of the full magnitude of the potential damage.

The risk that the exposure to cell phone electromagnetic radiation has been posing to the public is difficult to assess, due to two main problems. Firstly, radiation hazards are cumulative. Thus, over 10 years are needed for the demonstration of potential long-term cumulative health hazards in children that have been using cell phones and for the detection of the consequent health problems that might be developed due to long term exposure to radiation. All studies emphasize the need for further research data regarding long-term use. Secondly, the way in which cell phone environmental radiation standards is currently measured. Thus today it is typical to measure the total radiation within a house or a room over a period of 6 minutes. However this provides only one characteristic of the radiation field and does not provide a full representation of the exposure and the risks involved since the radiation field is non-constant. It is clear that under the same total radiation exposure, the biological response and the potential damage to the DNA as well as to other biological tissues is very different given that the radiation profiles are changing in time, space and variance. Recently, Friedman et al., 2007, have discovered for the first time a detailed molecular mechanism by which electromagnetic irradiation from mobile phones induces the
activation of the extracellular-signal regulated kinase cascade and thereby induces transcription and other cellular processes. These might pose a serious threat of cancer generation.

### SUMMARY OF THE INVENTION

The present embodiments are aimed at obtaining a representation of the radiation field in time and space, so as to provide the critical parameters of the radiation fields which human beings are exposed to, in urban and rural areas. The radiation field is provided per wavelength and changes over time may be included. The present embodiments provide urban radiation maps at several scales and present an algorithm to evaluate the magnitude and the variance of the field on different time scales.

According to a first aspect of the present invention there is provided apparatus for radiation mapping of a region comprising:

a spectrum analyzer for analyzing a local radiation field according to wavelength, and

a positioning unit for obtaining a position reading to correlate with said local radiation field, thereby to provide said radiation mapping.

The apparatus may further comprise a time correlation unit configured with time behavior of radiation fields, to correlate said analyzing according to wavelength with said time behavior, thereby to extrapolate a sample of said radiation field over a time period.

The apparatus may further comprise a superimposing unit configured to use said position reading for superimposing geographical information over said radiation mapping to produce an area map of said region including said radiation mapping.

The apparatus may further comprise an output selector for allowing a user to select between different frequencies, accumulated frequencies and times for showing in said area map.

In an embodiment, said positioning unit comprises a global satellite-based positioning unit.

The apparatus may be configured to provide readings to a resolution of substantially three meters.

The apparatus may further comprise said spectrum analyzer configured to include within said spectrum frequencies used in cellular telephony.

According to a second aspect of the invention there is provided a method of mapping a region for local radiation levels, comprising:

moving through said region;

at locations in said region detecting and analyzing a spectrum of interest for radiation levels over said spectrum;

associating each location analysis with an indicator of said location;

associating each location analysis with a sampling time; and

using said location indicators, superimposing said analysis on a map of said region.

In an embodiment, said radiation levels are cellular radiation levels having repeat patterns over a time interval, the method comprising using said sampling times to correlate said local analyses with said repeat patterns to provide a time dimension to said analysis.

The method may comprise:

applying said analysis with a frequency dimension to said map, and

providing to said map an interface for allowing users to access said analysis according to said frequency dimension.

The method may comprise applying said analysis with said time dimension to said map, and providing to said map an interface for allowing users to access said analysis according to said time dimension.

The method may comprise selecting locations at a resolution of substantially three meters.

The method may comprise finding peak radiation regions at given locations and providing consumers with dedicated devices tuned to the peak radiation. Thus the consumers are able to monitor their own radiation environments and yet do not need to go to the expense of obtaining a spectrum analyzer.

The user dedicated devices can be retuned when the overall mapping indicates a change in peak frequencies at the particular location.

According to a third aspect of the present invention there is provided a method of mapping a radiation spectrum of interest to a region of interest, radiation levels in said spectrum obeying a periodicity, said periodicity defining a period, the method comprising:

obtaining samples at locations in said region at frequency intervals in said spectrum, each sample being obtained at a certain sample time,

for each frequency at said sample time, using said periodicity to extrapolate said sample to said period,

adding each of said extrapolated samples to a geographical map of said region of interest, as a series of layers on a time dimension, such as to provide a layer on said geographical map for each frequency time combination.

The method may comprise providing an additional series of layers for cumulative radiation over said spectrum of interest.

The method may comprise providing a user interface for allowing a user to define one of said layers for display.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

Implementation of the method and/or system of embodiments of the invention can involve performing or completing selected tasks manually, automatically, or a combination thereof. Moreover, according to actual instrumentation and equipment of embodiments of the method and/or system of the invention, several selected tasks could be implemented by hardware, by software or by firmware or by a combination thereof using an operating system.

For example, hardware for performing selected tasks according to embodiments of the invention could be implemented as a chip or a circuit. As software, selected tasks according to embodiments of the invention could be implemented as a plurality of software instructions being executed by a computer using any suitable operating system. In an exemplary embodiment of the invention, one or more tasks according to exemplary embodiments of method and/or system as described herein are performed by a data processor, such as a computing platform for executing a plurality of instructions. Optionally, the data processor includes a volatile memory for storing instructions and/or data and/or a non-volatile storage, for example, a magnetic hard-disk and/or removable media, for storing instructions and/or data. Optionally, a network connection is provided as well. A display and/or a user input device such as a keyboard or mouse are optionally provided as well.

### BRIEF DESCRIPTION OF THE DRAWINGS

Some embodiments of the invention are herein described, by way of example only, with reference to the accompanying drawings. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIG. 1 is a simplified block diagram of a device according to a first aspect of the present invention that may be taken around a region of interest to map the spectrum across the region;

FIG. 2 is a simplified block diagram showing apparatus for assembling the data gathered in FIG. 1 into a multi-dimensional layered map according to a preferred embodiment of the present invention;

FIG. 3 is a simplified flow chart showing the operation of the apparatus of FIGS. 1 and 2 according to a preferred embodiment of the present invention;

FIG. 4A-4D are four graphs showing signal frequency against mean, standard deviation, average noise and mean emf with noise removed respectively;

FIG. 5 is a map of a geographical region whose radiation field was measured using a prototype of the present invention. The track taken by the measuring instrument is shown;

FIG. 6 illustrates cumulative radiation readings made over the track shown in FIG. 5;

FIGS. 7A-7C show cumulative radiation levels for the same street for different days and times;

FIGS. 8A-8C are 3-dimensional plots showing the log of the energy (log E) as a function of frequency (in MHZ). The three maps are for the same times on the same three days as in FIGS. 7A-7C;

FIG. 9A-9C show respectively the scan statistics for each of the three days, showing the signal mean and standard deviations;

FIGS. 10A-10G show the measurements for total energy 10a and per frequency 10b-10g for six separately defined frequency channels;

FIG. 11 shows the cumulative results superimposed over a geographical map of the area in question;

FIG. 12 shows three plots of readings taken from a stationary location in Tel Aviv which was sampled every 30 seconds. The three plots are total energy, filtered low frequency changes and the remainder of the signal after filtering, showing that low frequency changes are highly periodic whereas high frequency changes are relatively stationary;

FIG. 13 shows the high frequency changes plotted against a Gaussian curve, to show that the stationary part of the signal is essentially random;

FIG. 14 shows sampling results for the same antenna being sampled at two different sampling rates, in order to derive a best sampling rate in which separate samples are not correlated to each other;

FIG. 15 shows a probability against sampling time of measuring extreme values for a given antenna;

FIG. 16 shows the results of a Monte Carlo experiment for deriving sampling times; and

FIG. 17 shows mean curves of a Monte Carlo experiment for three different sources.

### DESCRIPTION OF EMBODIMENTS OF THE INVENTION

The present invention, in some embodiments thereof, relates to a radiation mapping system, method and device and, more particularly, but not exclusively, to such a system, method and device for measuring radiation pollution in the urban environment. In particular the present embodiments provide a system that is sensitive to highly localized changes in the radiation field, such highly localized changes being typical of cellular radiation in the urban environment.

The present embodiments may generate more or less detailed urban radiation maps of the cellular radiation field, which show the radiation distribution in spatial, temporal and frequency domains. Embodiments of the present method are based on repetitive spectral measurements, which allow a determination of the distribution of the mean and extreme values of the radiation for each antenna in the studied area. A sampling scheme is provided together with an algorithm to measure effectively the new statistical parameters of the radiation field which are required to create urban maps using a statistically robust strategy that minimizes the effort of making measurements, in frequency, time and in space, while maximizing the accuracy.

The present embodiments may obtain a full representation of the radiation field in time and space, so as to provide the critical parameters of the radiation fields which human beings are exposed to, in urban and rural areas. Urban radiation maps in several scales may be created and an associated algorithm evaluates the magnitude and the variance of the field in different time scales.

Before explaining at least one embodiment of the invention in detail, it is to be understood that the invention is not necessarily limited in its application to the details of construction and the arrangement of the components and/or methods set forth in the following description and/or illustrated in the drawings. The invention is capable of other embodiments or of being practiced or carried out in various ways.

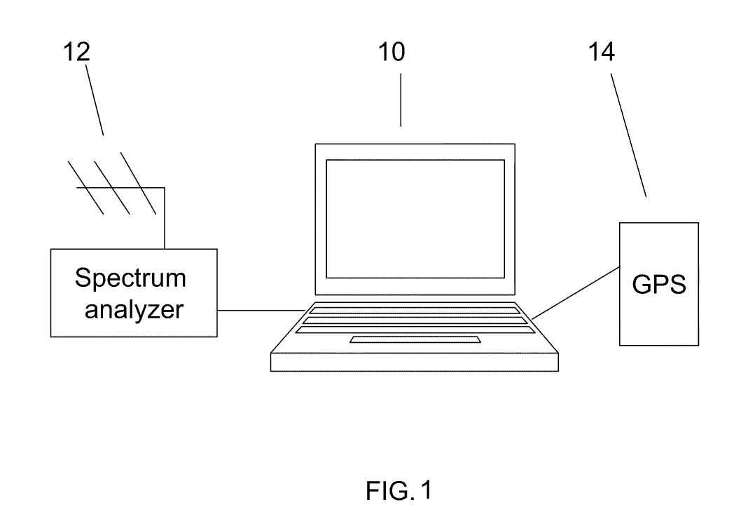

Referring now to the drawings, FIG. 1 illustrates apparatus for radiation mapping of a region. The apparatus may be taken in a car or may even be designed to be carried in a rucksack so that it is mobile.

The apparatus includes computer 10 which connects a spectrum analyzer 12 and a position measuring device such as GPS unit 14. The GPS unit may provide for a resolution of up to three meters. The computer 10 may be a laptop-type computer to combine effective computing power with portability.

The spectrum analyzer is for analyzing a local radiation field according to wavelength. A simple and relatively rapid measurement characterizes the energy levels at the different frequencies across the spectrum, which can be downloaded to computer 10. The spectrum analyzer may be set to make a broad sweep of the spectrum or may concentrate on wavebands of particular interest, such as cellular and radio wavebands and wavebands known to be in use by the police or the military, or otherwise present in the region. A vicinity in which GSM wavebands are in use may require sweeping of the these wavebands and a vicinity in which CDMA is in use may require sweeping of the CDMA wavebands.

The positioning unit obtains a position reading to store with the local data analysis. The position reading is correlated with the respective local radiation field in the computer so that the computer stores the data with a spatial dimension so that subsequent mapping of the data to a geographical map may be carried out.

As will be explained below, cellular telephony radiation levels show periodic behavior over the day, since the people using the cellular telephones tend to follow daily cycles themselves. Thus the incoming data can be correlated with this periodic behavior to give a picture from a single reading taken at a single time, of the radiation levels for the whole day. For this purpose the incoming sample data may be given a time stamp.

The apparatus shown in FIG. 1 may be provided in a vehicle portable version or as a person-portable version. As the latter the apparatus may require a rucksack or the like. In either case the apparatus is taken around the region of interest, sampling data automatically as it goes.

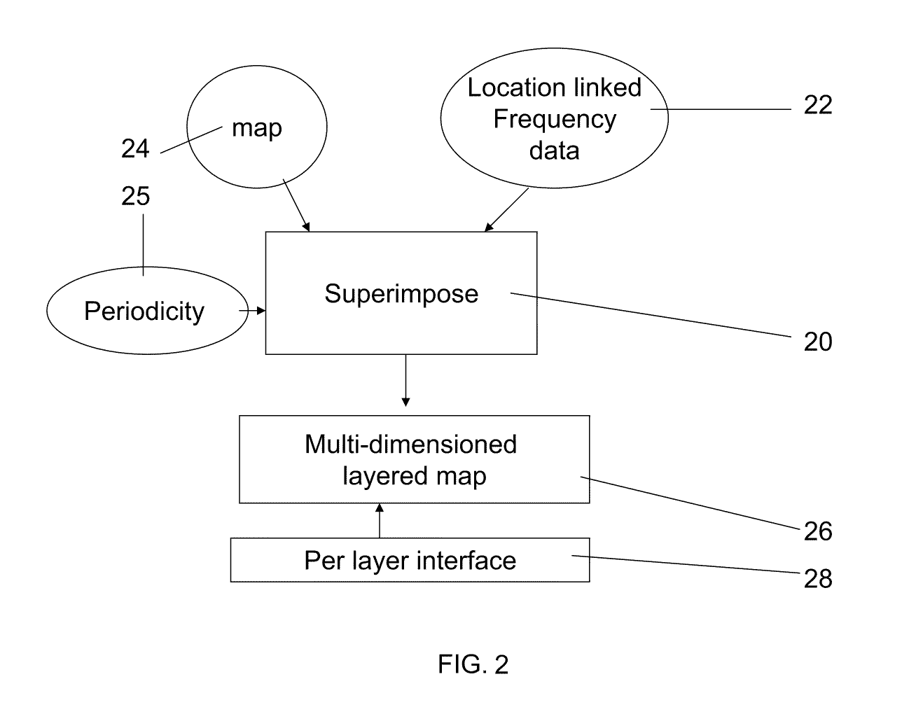

Reference is now made to FIG. 2, which is a simplified diagram showing how the data gathered using the apparatus of FIG. 1 may be applied to a map. A superimposing unit 20 takes the location linked frequency data 22 and uses the position reading to superimpose the radiation mapping over a geographical map of the region of interest 24. The radiation data may be provided as an additional layer over the geographical information already on the map, to provide a layered map 26. As will be explained the radiation data may also have a time dimension and different times may be superimposed as separate layers on the map. The periodic behavior of the given frequency over the day may thus be provided as an additional input to the superimposing unit 20. It is noted that on initial mapping, only a general periodicity may be available, say based on a single antenna source in the region, but as the region is sampled more and more, at different times of the day, a more local picture of the periodicity may be accumulated and thus the system self-learns. The initial measurements may be more detailed and frequent to provide better statistics.

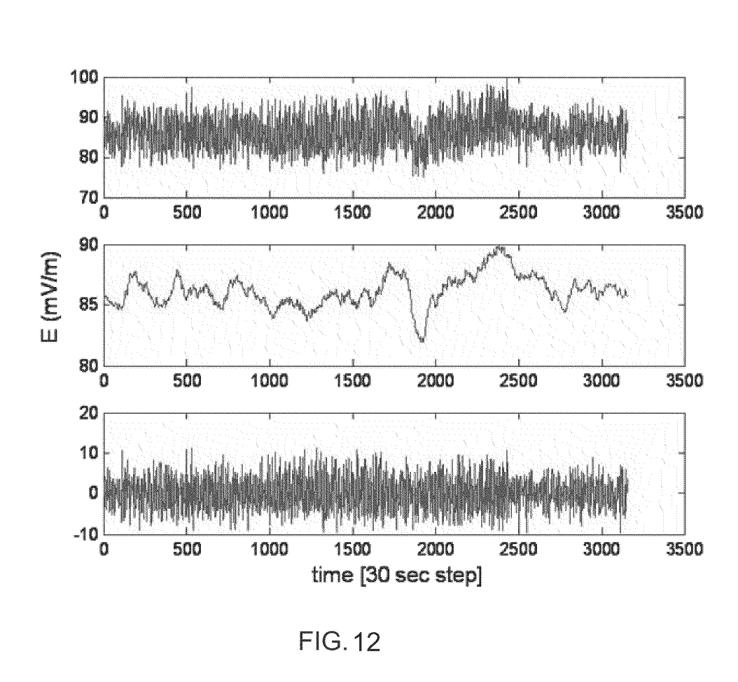

As will be explained below, the radiation from a source tends to show periodic behavior at a low frequency and Gaussian behavior at a higher frequency. An overall time profile for any given signal can thus be constructed by superimposing a periodic signal on a Gaussian, as discussed in greater detail hereinbelow, specifically with respect to FIG. 12.

The radiation data also has a frequency dimension and the different frequencies may also be represented as separate layers on the map. Each frequency would thus have its own time dimension. In addition there may be an additional layer for cumulative radiation, and this too would have a time dimension. The result is to provide a multi-dimensional layered map in which radiation levels are shown cumulatively and at different frequencies at different times, and each frequency/time combination gives rise to a different layer of the map that can be separately accessed through a suitable interface that gives per layer output.

The interface 28 may provide an output selector for allowing a user to select between the different frequencies, accumulated frequencies and times to provide an informational way of interacting with the multi-dimensioned layered map 26.

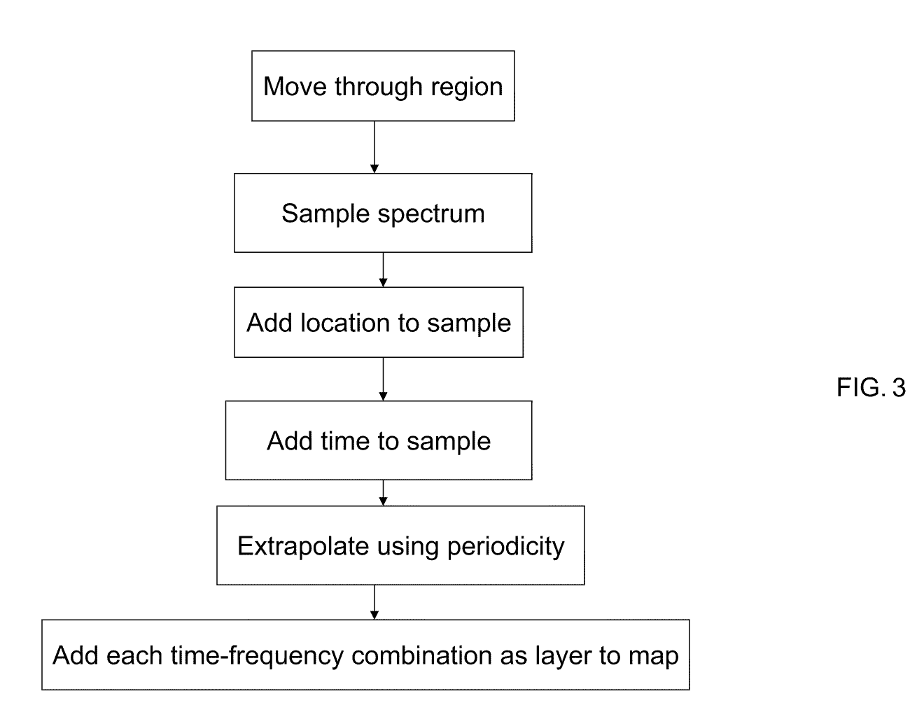

Reference is now made to FIG. 3, which is a flow chart illustrating the broad process described above. The process of taking samples involves moving through the region and continually taking samples on the move across the spectrum of interest. Each sample comprises radiation levels at different frequencies within the spectrum for the given time at which the sample is taken.

The analysis may then be superimposed on a geographical map.

Such superposition may involve obtaining the samples as described, and for each frequency level extrapolating the sample according to the periodicity. The extrapolation may be for a period defined by the periodicity. Then each sample as extrapolated may be added to a geographical map of the region of interest, as a series of layers on a time dimension. That is to say a layer is constructed for the map for all of the samples for a given frequency at a given time. Thus each frequency/time combination becomes a different layer. Each frequency thus produces a set of layers. The main 6 layers for each region may include: 1. Total field energy 2. Standard deviation of the total field 3. Maximum of the total field 4. Maximum of the mean of all frequencies 5. Maximum of the standard deviation of all frequencies 6. Maximum of the maximum of all frequencies.

A cumulative layer may also be provided, that is a set of layers showing cumulative radiation over the spectrum. Each individual layer would show cumulative layer across the region for a given time.

The embodiments and aspects of the present invention as delineated hereinabove and as claimed in the claims section below are now described in relation to an example prototype with experimental results.

In the example prototype, the Electromagnetic Field was measured using a multifunctional Spectrum Analyzer Will'tek 9102 with the 9131 EMF Measurement Option and Will'tek 9171 antenna. In this configuration, the Will'tek 9102 enables measurement of the EMF (Electromagnetic Field) over a predefined frequency range and displays the field strength in units of V/m. The Will'tek 9102 has a frequency range of 100 kHz to 4 GHz, resolution bandwidth (RBW) of 1 kHz, dynamic range of 70 dB and it has displayed average noise level of −117 dBm. The 9171 antenna has a frequency range of 300 MHz to 3 GHz and sensitivity better than 5 mV/m.

The prototype used the Magellan Explorist 210 with TrueFix GPS technology, 14 parallel channels, supported by WAAS and EGNOS Satellite-Based Augmentation Systems for accuracy within a 3 meters range.

The spectrum analyzer data and the GPS input were taken to a portable computer, thereby allowing measuring of EMF and location simultaneously. The system was mounted on a car or used in a backpack while walking.

The GPS was connected to the computer by serial interface and NMEA 0183 protocol. Latitude/longitude data were stored to ASCII file. The Spectrum Analyzer was connected to the computer by LAN interface and to the Will'tek 9100 Data Exchange Software which stored the frequency scans as ASCII files. Both GPS and Spectrum Analyzer data were recorded with Current System time (PC time) to synchronize both outputs.

The frequency range of the spectrum analyzer was chosen to measure all possible cellular frequencies and this involved setting the analyzer to a range of 500 MHz to 2.5 GHz. The resolution bandwidth was set to 1 MHz, completing each scan in 237 millisecond. The data from the spectrum analyzer was recorded every second, which resulted in about 15 m between two scans when driving at about 55 Km/hour, and of course a higher resolution was obtained from walking. The output data files were stored with a final RBW of 4 MHz, and this was due to the processing procedure of the Will'tek 9102.

The results were provided in two matrixes using the system time to synchronize the Spectrum Analyzer and GPS outputs. The first, GPS_{i×3}, includes the 3 vectors of latitude, longitude and Time. The second, DATA_{i×511}, includes 511 discrete frequencies for each scan which was recorded during the run.

The GPS output has some irregular timing and varying accuracy during driving, and this is believed to be due to the following:

a. the NMEA protocol does not transmit latitude/longitude data every second.

b. the GPS calculation is disturbed while satellites enter and exit the line of sight.

c. the position data accuracy does not reach the theoretical 3 m accuracy during movement of the GPS.

The result of the above is that the number of the Spectrum Analyzer output files exceeds the GPS readings.

In order to compensate for the above and provide location for each scan it is possible to first expand the GPS data using linear interpolation so that the DATA rowⁱ and GPS rowⁱ match for every second of the run. It is noted that the above problems are not observed when walking.

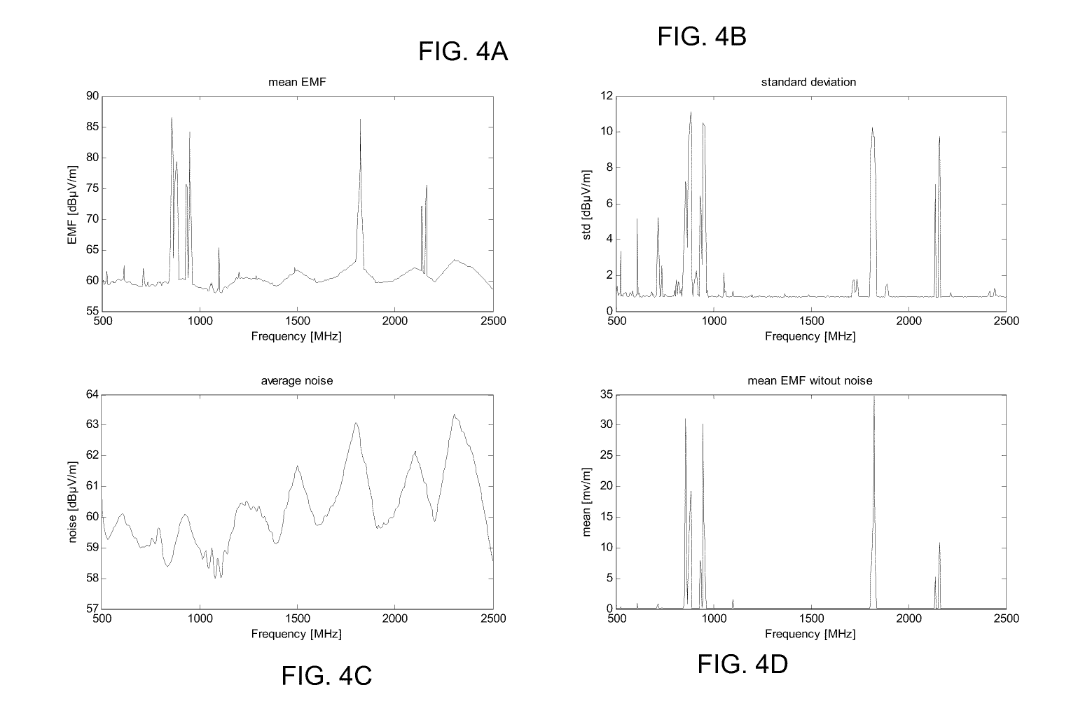

Noise removal from the measurements is now discussed with relation to FIGS. 4a-4d, which are graphs showing frequency against EMF. FIG. 4a shows frequency against mean EMF. FIG. 4b shows frequency against standard deviation. FIG. 4c shows frequency against average noise, and FIG. 4d shows frequency against mean EMF without noise. The mean and the standard deviation EMF over time indicate that the data (base station radiation) is riding on a steady noise which probably originates from the electronics of the instrument. It is thus possible to use a standard deviation threshold to isolate the noise from the measurements since the standard deviation over channels with distinct base station radiation is considerably greater than the standard deviation of low-level radiation channels.

In order to define the noise level, as per FIG. 4c one may take from the mean EMF vector only the entries with standard deviation lower than the threshold, and then use spline interpolation to fill empty entries. An EMF noise free signal may then be determined by taking from the data-matrix only entries with readings which are at least 6 dB higher than the average noise level. One may set all other entries to zero. The noise free mean EMF may then be converted to linear units to produce the result presented in FIG. 4d.

After having removed the noise from the DATA matrix, the EMF measurement may be analyzed in the time and frequency domains. The GPS data added to the samples allows the data to be analyzed spatially.

By observing the mean and STD of EMF against frequency, it became apparent that the radiation from different cellular service providers and at different frequencies, has a different behavior in time, and such behavior for frequencies of interest was identified, as will be explained below.

The entries in the matrix for the same frequencies at different locations were combined to create city radiation-level maps of each cellular band and of the total EMF. In places where more than one measurement was available for whatever reason, the highest EMF reading was taken.

In a field trial, field measurements were carried out in two locations: the Weizmann Institute and its vicinity in Rehovot, and in Tel Aviv. Table 1 summarizes the sampling that was carried out. Several sampling schemes were used and the measurement was designed to fully represent the radiation field in time and space, so as to enable map generation and signal analysis. Further testing was carried out by mapping in a relatively small area, by walking with the measuring device stored in a backpack or driving along city roads.

TABLE 1
Summary of sampling trials

| | | | Time | | |
|---|---|---|---|---|---|
| | | | between | Number of | Area |
| Time | Area | Method | scans | measurements | coverage |
| 10:00-11:30 | Tel-Aviv | Drive test | 1 sec | 3,275 | 1.5 km² |
| 13:30(8/12) to | Tel-Aviv | Fixed | 30 sec | 3,156 | ### |
| 15:44.(9/12) | (Masarik 11) | measurement | | | |
| 14:45-15:45 | Tel-Aviv | Fixed | 1 sec | 3,289 | ### |
| | (Masarik 11) | measurement | | | |
| 14:10-14:30 | Tel-Aviv | Walking with | 5 sec | 116 | 0.01 km² |
| | (Rabin | backpack | | | |
| | Square) | | | | |
| 13:32-13:44 | Weizmann | Walking with | 5 sec | 182 | 0.001 km² |
| | institute for | backpack | | | |
| | science | | | | |
| | (wolfson | | | | |
| | square) | | | | |
| 13:49-13:59 | Weizmann | Walking with | 5 sec | 182 | 0.001 km² |
| | Institute of | backpack | | | |
| | science | | | | |
| | (playground) | | | | |
| 14:20-14:35 | Rehovot, | Drive test | 1 sec | 735 | 0.3 km² |
| | science park | | | | |
| 15:05-16:05 | Tel-Aviv, | Drive test | 1 sec | 3289 | 1.5 km² |
| | including | | | | |
| | Hamedina | | | | |
| | Square | | | | |
| 14:08-14:20 | Rehovot, | Drive test | 1 sec | 656 | 0.3 km² |
| | science park | | | | |
| 14:41 15:47 | Tel-Aviv, | Drive test | 1 sec | 3240 | 1.5 km² |
| | including | | | | |
| | Hamedina | | | | |
| | Square | | | | |
| 13:45-13:55 | Weizmann | Walking with | 5 sec | 119 | 0.005 km² |
| | institute for | backpack | | | |
| | science | | | | |
| | (wolfson | | | | |
| | square) | | | | |
| 13:59-14:09 | Weizmann | Walking with | 5 sec | 118 | 0.005 km² |
| | institute for | backpack | | | |
| | science | | | | |
| | (playground) | | | | |

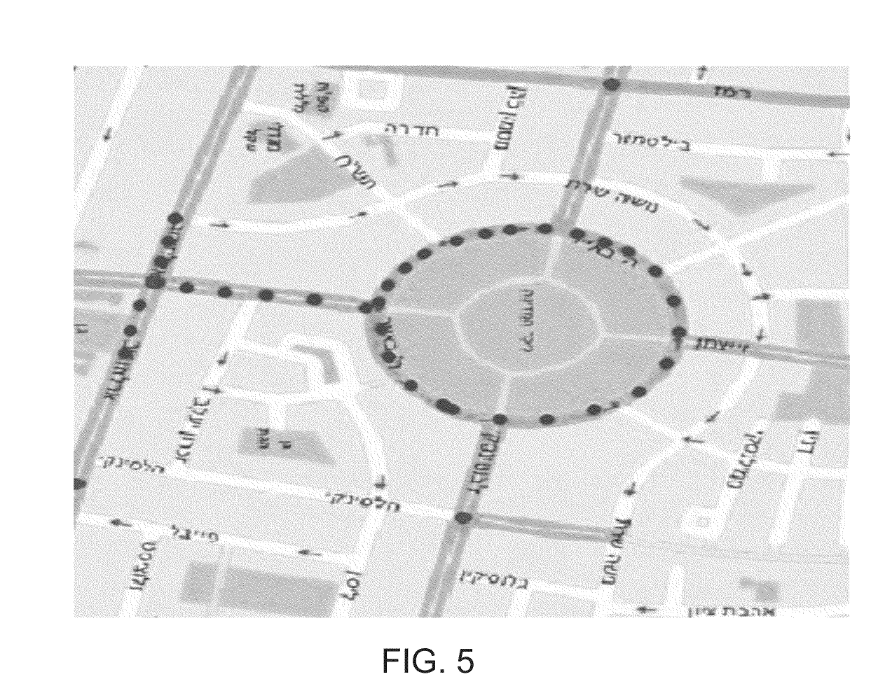

For the sake of brevity, results are shown only for Hamedina Square in Tel Aviv to demonstrate the capabilities of the measuring procedure and the algorithm for processing the results. A physical map showing the general area is given in FIG. 5, and the square and the main streets around can be seen. Purple dots represent the route taken by the car making the measurements. All 6 layers mentioned hereinabove can be generated. We focus in the following on several examples.

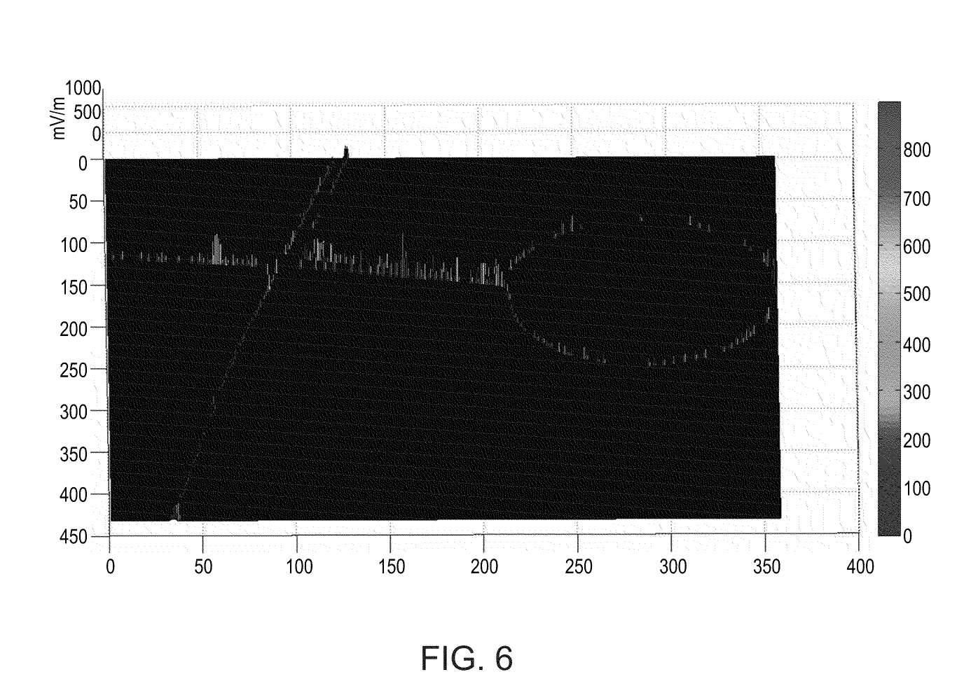

FIG. 6 is a layer that can be superimposed over the map of FIG. 5. FIG. 6 is created from the readings and shows the total energy of the area across the spectrum of interest in units of mV/m. The map indicates local maxima and minima along the driving track.

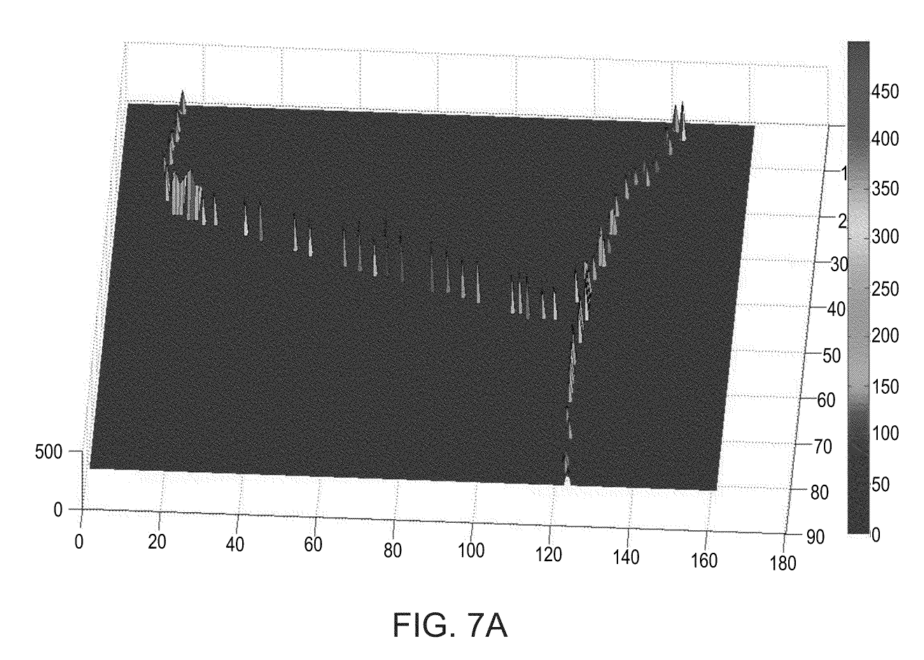

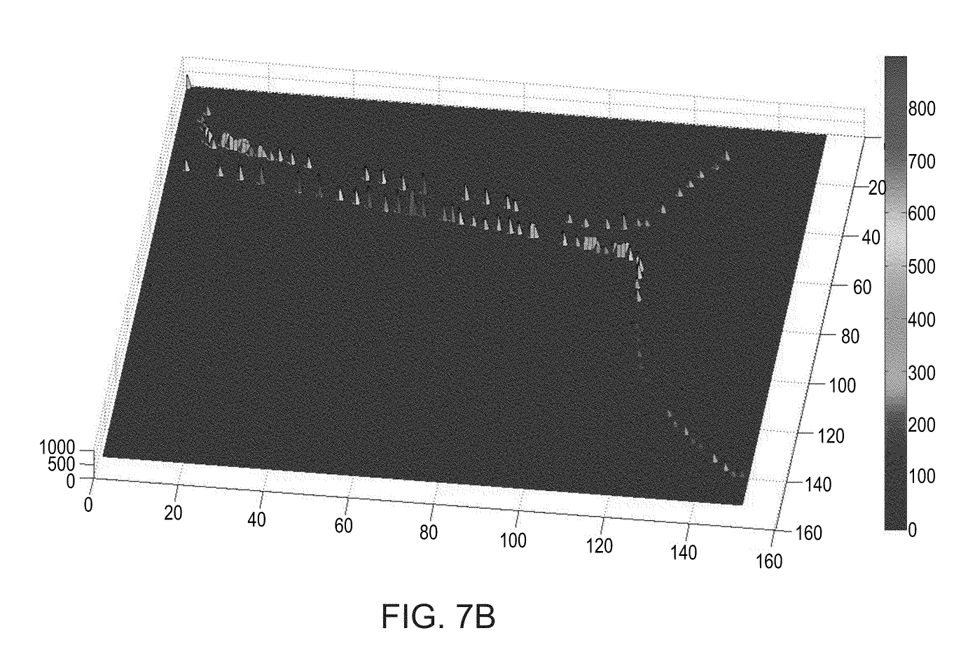

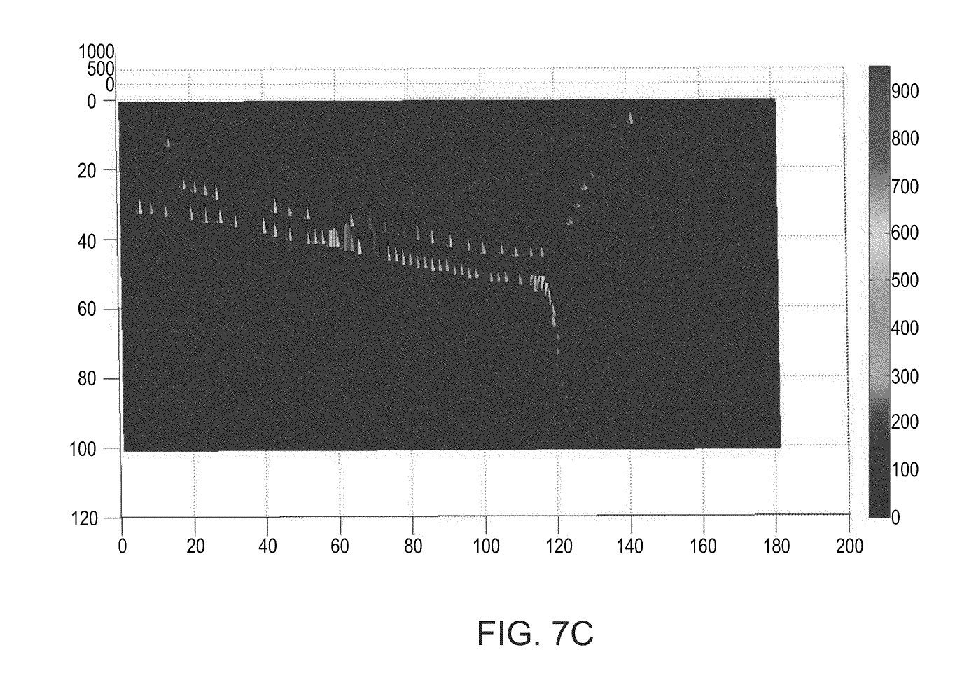

Reference is now made to FIGS. 7a, 7b and 7c which are three total energy maps of the same streets on different days and at different time of the day. FIG. 7a shows a Friday morning at 11:00 AM; FIG. 7b shows the same location on Tuesday at 15:30 PM; and FIG. 7c shows the location on Wednesday at 15:30 PM. Note the maximum scale at 7b and 7c is twice as much as the maximum in 7a, although the colors are the same. The reader should note that in Tel Aviv, Tuesday afternoon is a time when many smaller shops are shut, but most businesses are open. Wednesday is a full part of the working week, and on Friday morning schools and shops are open but many businesses are shut.

FIGS. 7a-7c show the variability in total energy in the same streets over a period of three different days at different times of the day. A large variability was observed over the three days of measurement, both in time and space. FIGS. 7b and 7c show separate measurements at either side of the street, from which it may be seen that the different sides of the street, in this case Weizmann St., do not show the same radiation levels and that the present methodology is sensitive enough to capture these changes.

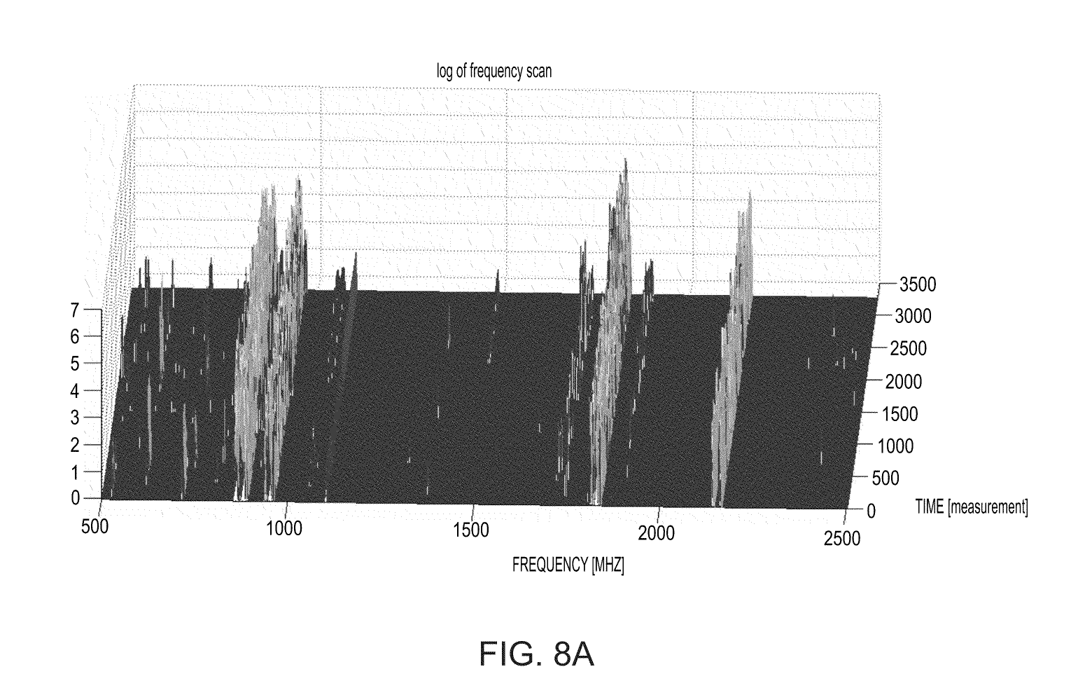

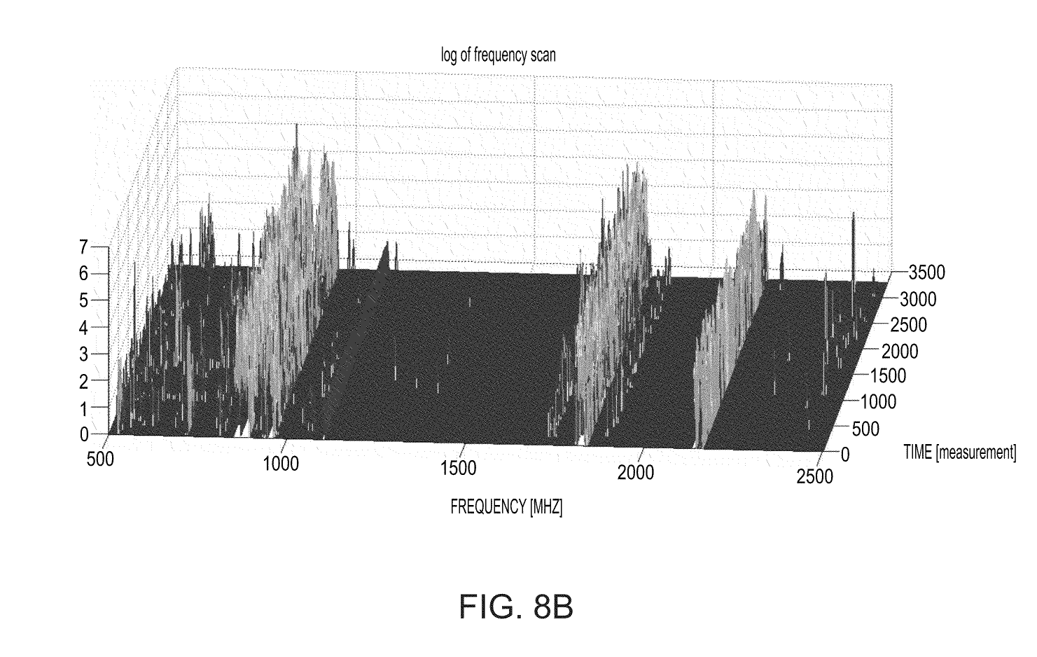

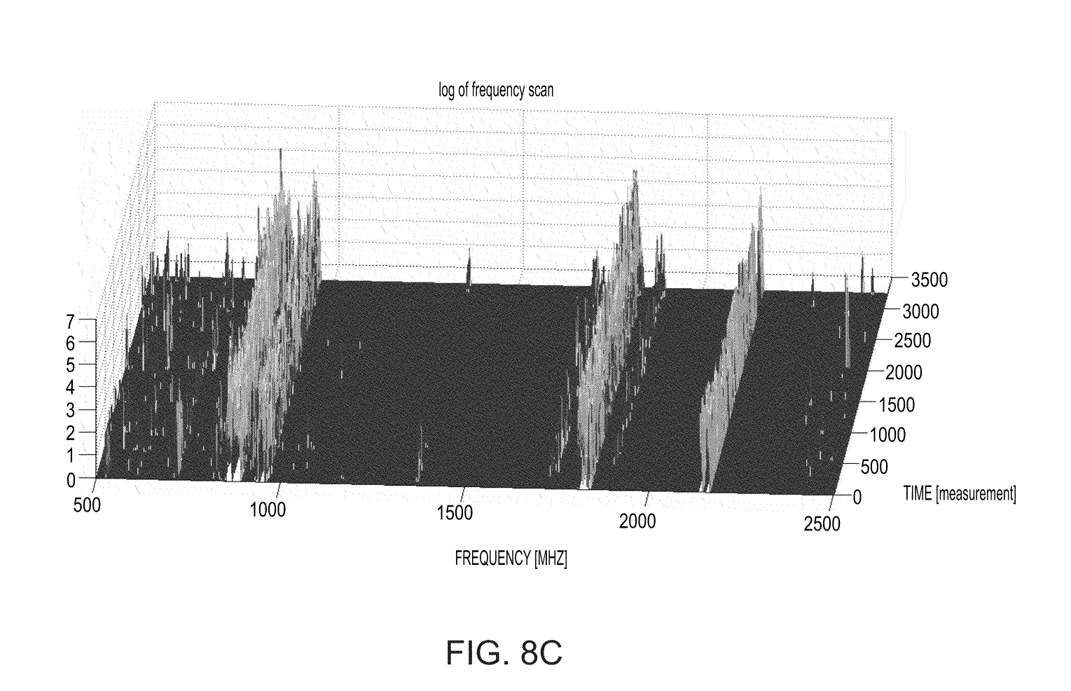

Reference is now made to FIGS. 8a-8c. FIGS. 8a-8c are 3-dimensional plots showing the log of the energy (log E) as a function of frequency (in MHZ). The three maps are for the same times on the same three days as in FIGS. 7a-7c, that is 8a is for Friday, 8b is for Tuesday and 8c is for Wednesday.

FIGS. 8a-8c show the spectral distribution of the energy field for these three days. It is clear that most of the energy is carried in 3-4 spectral bands, but additional radiation is present in other bands and in sporadic time.

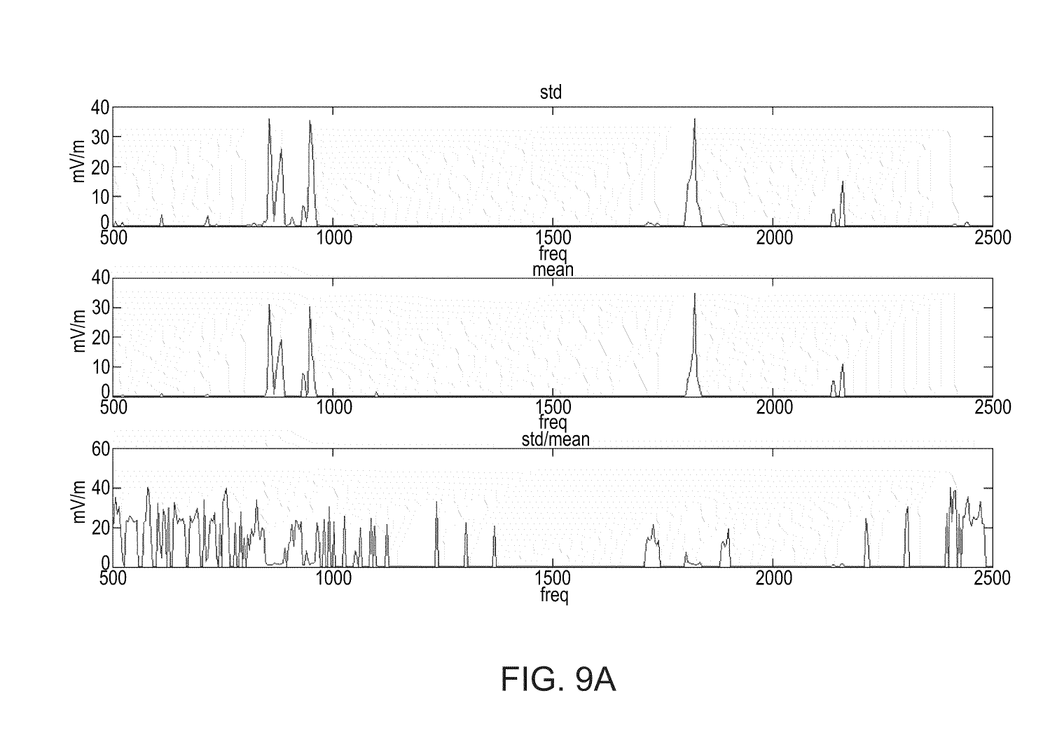

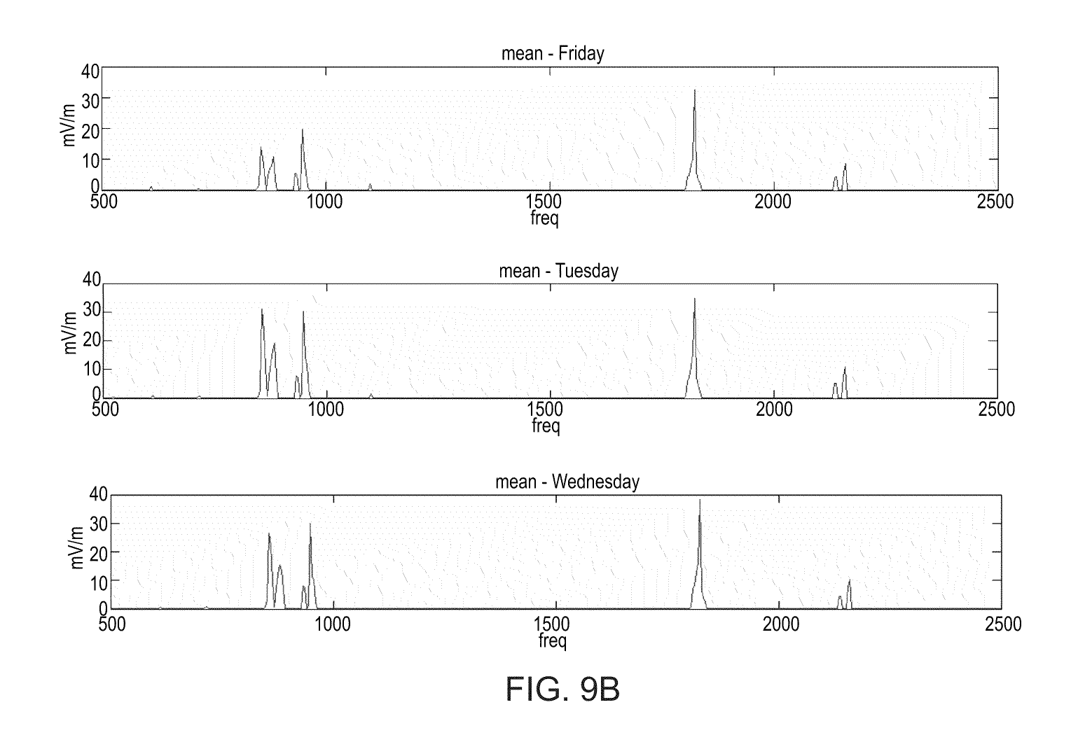

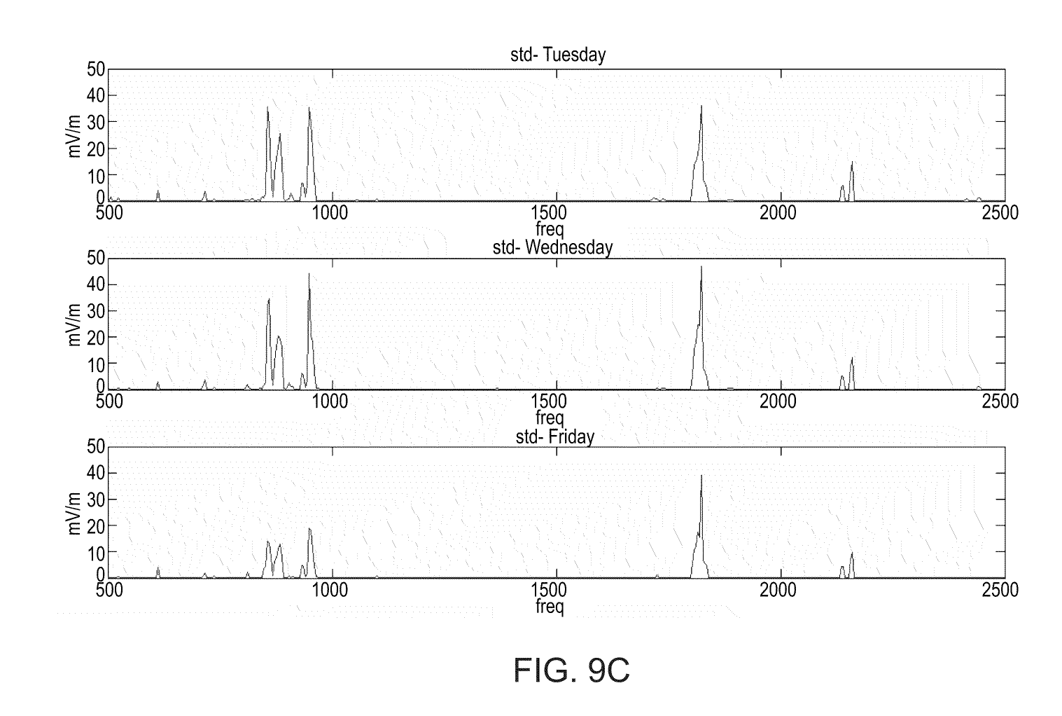

Reference is now made to FIGS. 9a-9c. The scan statistics of the measurements from each scan are presented in FIGS. 9a-9c, where FIG. 9b shows the mean for each day and FIG. 9c shows the standard deviation for each day. These show that the standard deviation of the energy in each frequency band is as large as the mean. The comparison of the mean and the standard deviation among the three different days as presented in FIGS. 9b and 9c, demonstrate the large temporal variability of the radiation.

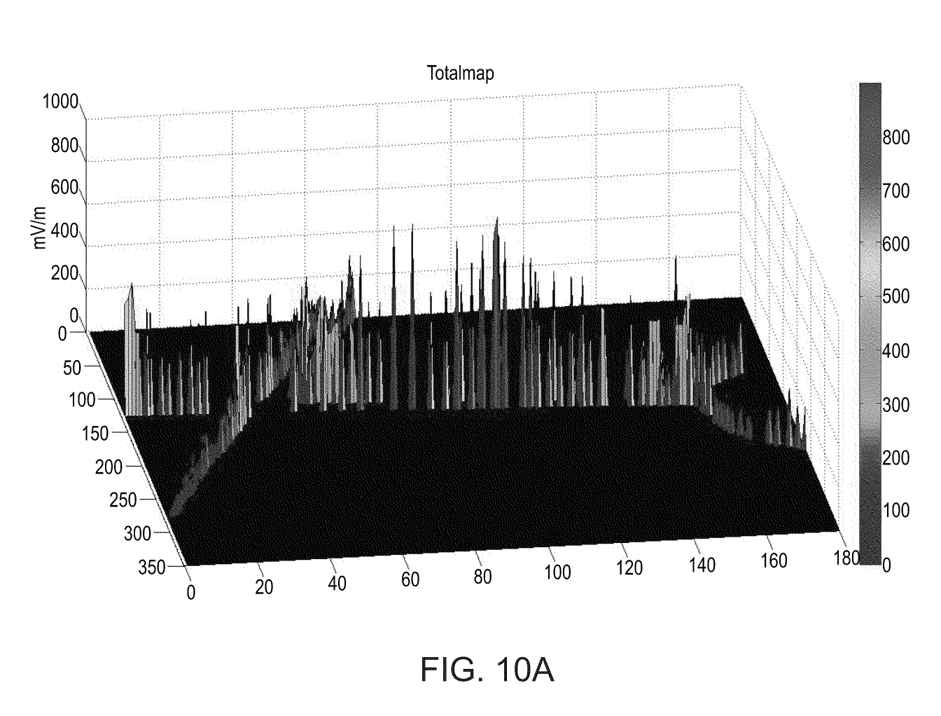

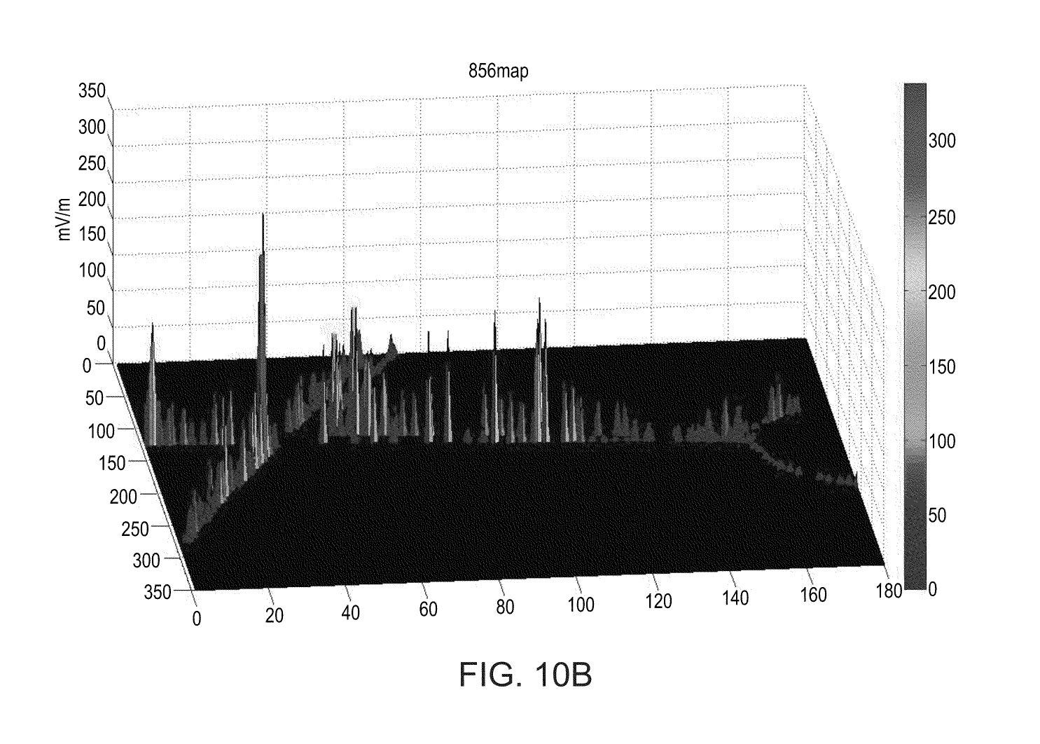

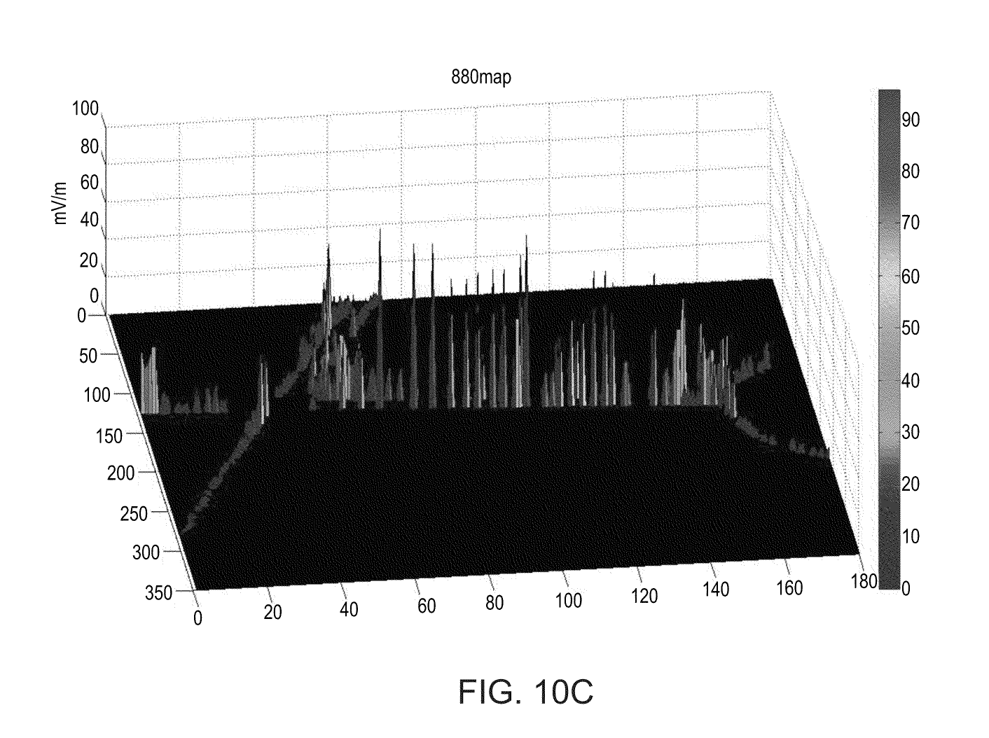

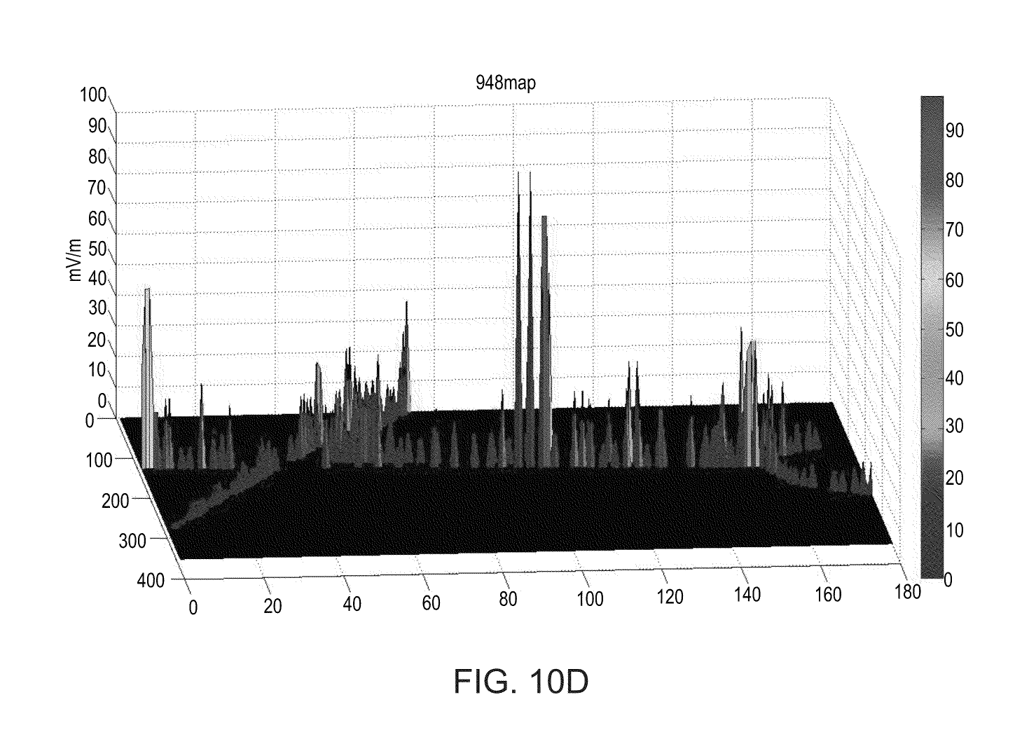

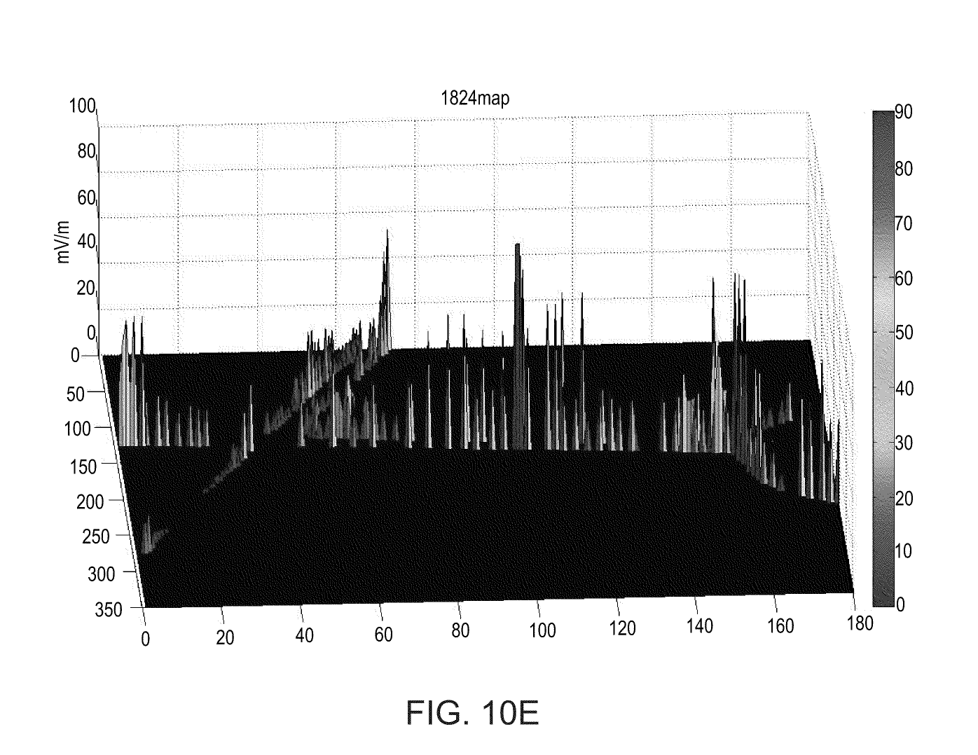

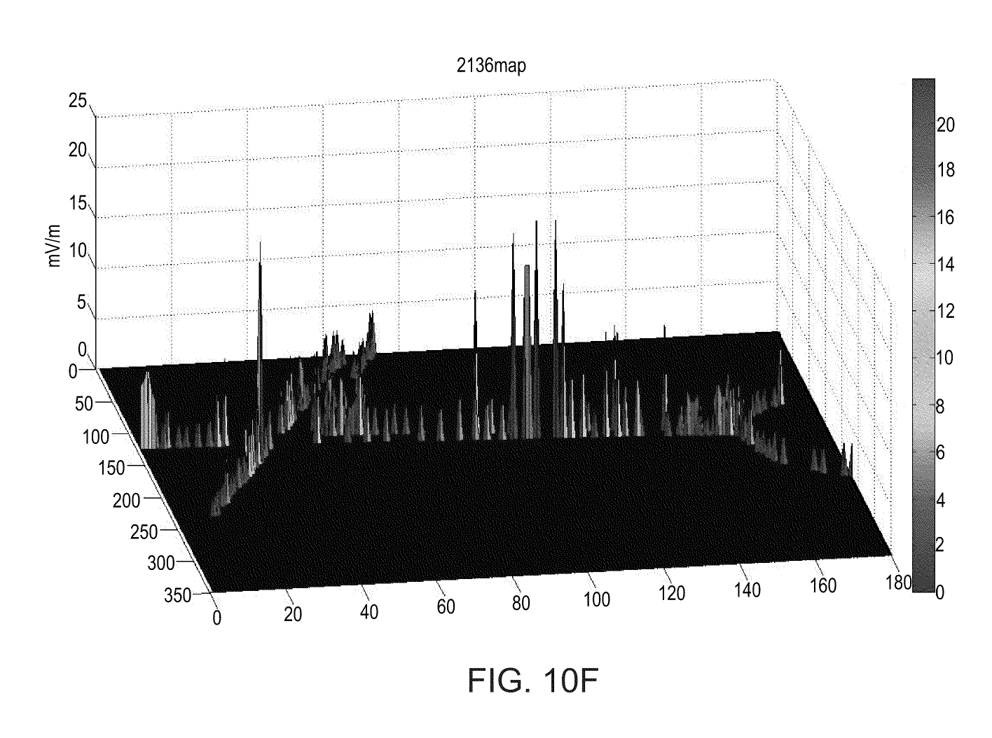

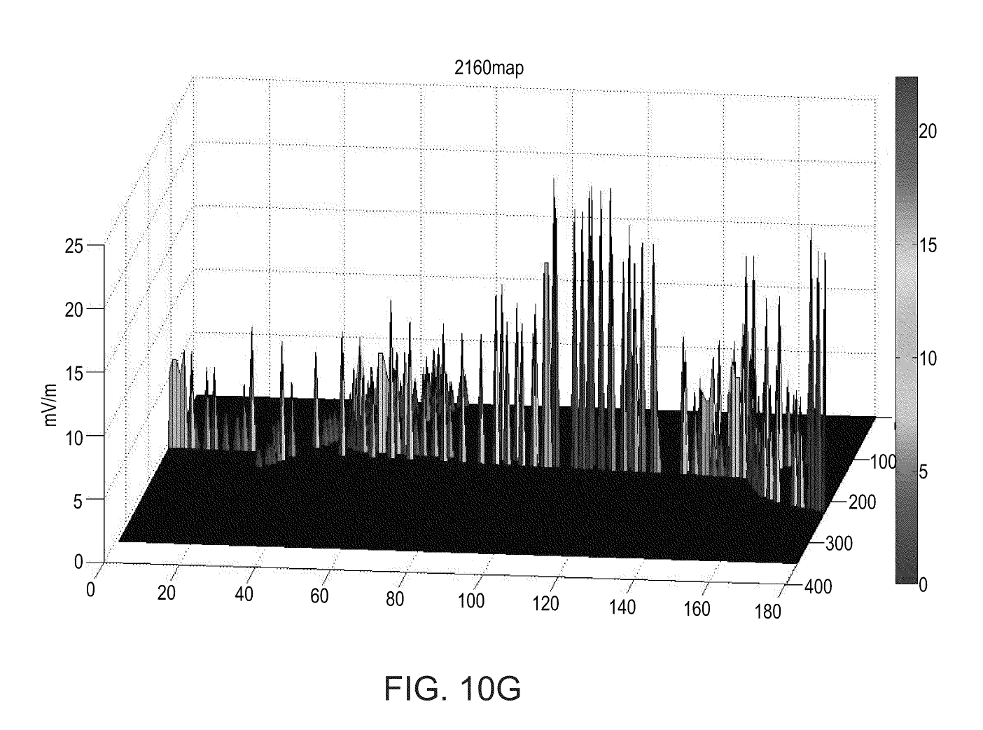

Reference is now made to FIG. 10a-g. These seven plots present the radiation map for Weizmann Street in total—FIG. 10a and in each of six major frequency bands in FIGS. 10b-10g. There is a large spatial variability in each frequency. Moreover, the location in the street where the maximum energy is measured is different for each frequency band.

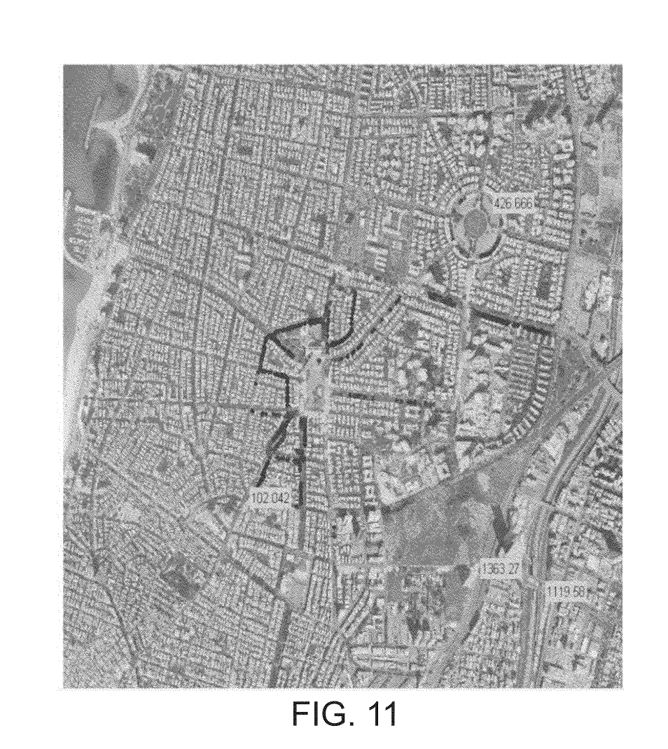

Reference is now made to FIG. 11, which shows a physical map of Tel Aviv, in fact in this case a GIS (geographical information system) map, superimposed with total radiation measurements as per FIGS. 4a-4c.

In summary, the measurements made in the above example show that the radiation field is characterized by a high level of spatial and temporal variability, both in the total energy and in specific frequency bands. The field changes over very short time scales and varies by more than 100% at distances that are in the order of several meters.

The above makes it possible to question the current way by which cellular radiation field information is measured, in order to estimate any hazards associated therewith. It is suggested that more detailed information than just the mean energy loading should be considered when assessing radiation risk levels to the public. It is not well understood yet what and how the biological tissue reacts to the presence of electromagnetic (EM) radiation and what are the most important statistical parameters to use in order to estimate the risk. Theoretically it is not clear if the probability for a biological cell to be modified is high when the average EM field is high or when a sudden changes in the field occurs or any danger may instead correlate with maximum values, which occur for a relative short times, but which are many orders of magnitudes higher than the average.

We argue that statistical parameters such as maximum radiation, standard deviation, and the change rate of the radiation in time (EM time derivative) may be important factors in such a possible biological interaction. Moreover, as in many other EM related fields, time and frequency are symmetric and a detailed analysis of the EM properties may be carried out in both domains.

When developing a method to measure effectively such statistical parameters and to create urban maps of these fields, it is desirable to develop a statistically robust strategy that will minimize the effort of measurement, in frequency, time and in space, while maximizing the accuracy of the measures. Specifically, one needs to measure the EM spectra continuously, to cover a large area and to capture the local properties of the radiation field.

Given that one cannot actually measure the entire area all of the time a best measurement strategy must be considered. To define the best measurement strategy the following questions need to be dealt with:
1) What is the coarsest frequency resolution (df) that can be used to capture most of the cellular characteristics?
2) Can the cellular radiation field be approximated with a stationary variable?
3) For a given cellular frequency, with respect to the first moments (mean, max, std), what can be considered local in space—or what is the spatial scale.
4) What is the maximum sampling time (dt) that captures the statistics of the temporal variations of a given antenna? And for a given location what is the minimum time of measurement (T) that captures the statistics of the antennas at this point?

Based on highly frequent measurements in Tel Aviv and in the Weizmann Institute it was determined that the maximum frequency step that can capture the information may be defined directly by Shannon's law. The frequency transform of the frequency domain (FFT of the spectra) revealed that with df=4 MHz the highest frequency in the spectrum of interest may be sampled by at least two points and therefore all the information throughout the spectrum may be preserved.

Reference is now made to FIG. 12, which is a set of three graphs showing how a signal at a given frequency at a stationary location can be decomposed into periodic and random parts. To a good approximation, for each antenna, the measurements show that the radiation field can be decomposed into two components: a high frequency stochastic signal that has stationary properties and a low frequency signal with a clear diurnal cycle.

FIG. 12 shows three graphs of data recorded from a fixed point in Tel Aviv. The upper panel shows the raw energy data measured every 30 sec for 26 hrs. The mid panel shows the signal of the first panel filtered through a low pass filter with a length of 0.5 hrs. The lower panel shows the higher frequencies, that is the original signal less the low pass of the middle panel.

Some periodicity is apparent from the top graph. The middle graph is very periodic, and the lower graph appears to be distributed normally around the mean, as expected from a stationary signal.

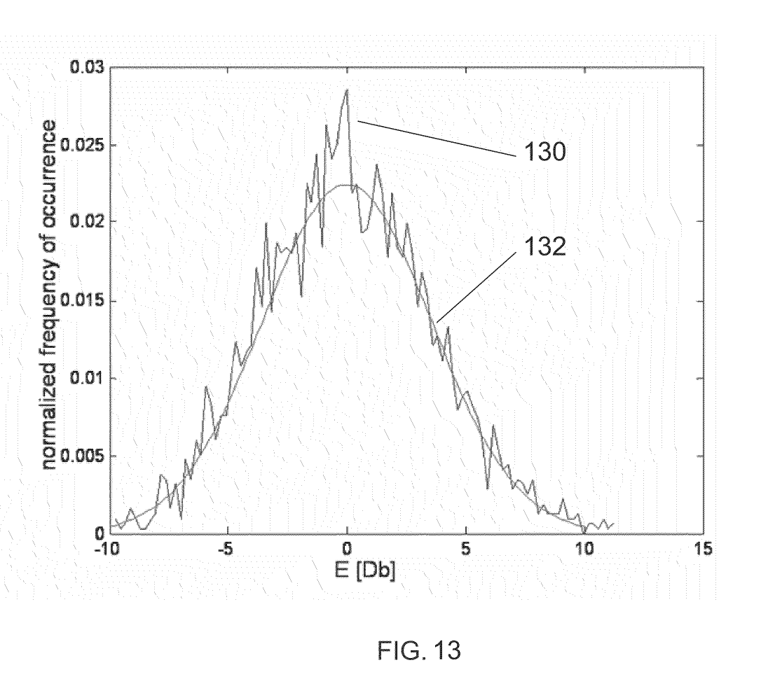

To illustrate the point, reference is now made to FIG. 13, which is a graph showing E in decibels against the normalized frequency of occurrence for the lower graph signal of FIG. 12. Graph 120 is the probability density function (PDF) of the signal shown in FIG. 12, that is of the lower panel arrived at after removing the low frequency fluctuations. The graph is shown against curve 122 which is the theoretical Gaussian distribution curve.

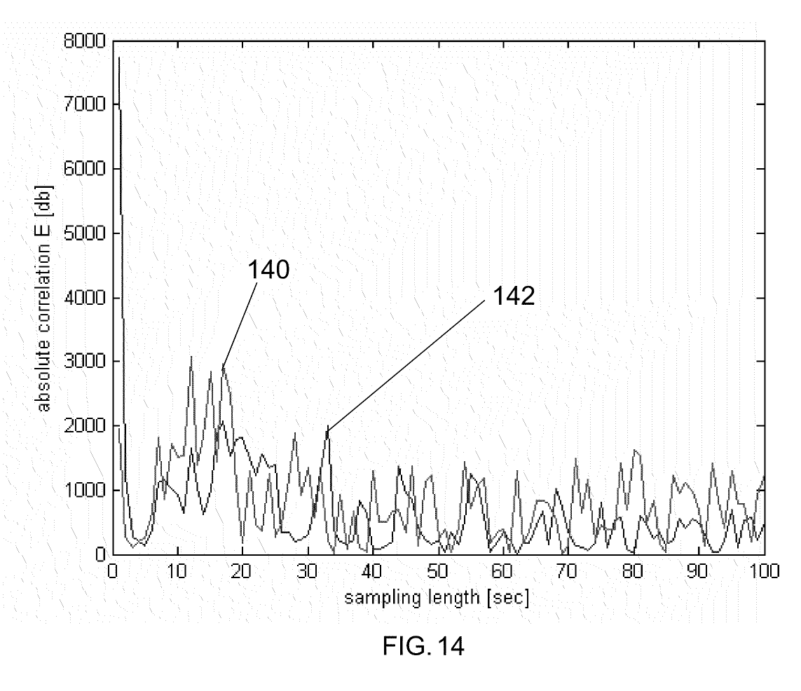

Reference is now made to FIG. 14 which illustrates how to set a sampling step. To use each sample from a given antenna, as an independent variable, one must make sure that the sample is not correlated to the previous ones. The best length of the sampling step dt that may capture the statistical properties may be defined by the autocorrelation properties of the antenna. dt will be bounded by the condition that the sampled signal is decorrelated. This promises no redundancy in the retrieved information and thus high efficiency in calculating the local statistical properties.

FIG. 14 shows the first 100 samples of the autocorrelation for two sampling rates of the same antenna. Curve 140 shows dt=1 sec and curve 142 shows dt=30 sec. It is apparent that for the short sampling rate 142 a very weak correlation can be seen on the first sample, that is the value is still less than the e-fold of the zero shift cross-correlation, while the signal 140 is completely decorrelated to a good approximation.

From FIG. 14 it is seen that for any practical use, a sampling rate of 1 sec can be used as decorrelated data and therefore can be assumed as independent. These results are used to define the minimum sampling time T per a given location. For decorrelated data the question can be translated to how many independent samples N need be collected to capture the local statistics. This can be answered by using the normal PDF properties of the radiation energy (per antenna).

$$P ( x ) = \frac{1}{σ \sqrt{2 π}} exp ( - \frac{{( x - μ )}^{2}}{2 {σ}^{2}} ) , \qquad ( 1 )$$

where P is the probability to measure radiation x with mean P and standard deviation σ. Integrating the normal PDF for value of one standard deviation above the mean (−∞≦x≦μ+σ) leaves out only the upper ρ=15% values. Assuming that the signal is measured in a decorrelated manner and therefore the measurements can be assumed to be independent, hence the probability Θ(N, ρ) to measure at least one measurement that will be larger than the upper ρ in N measurements is:

Θ(N,ρ)=1−(1−ρ)^{N}. (2)

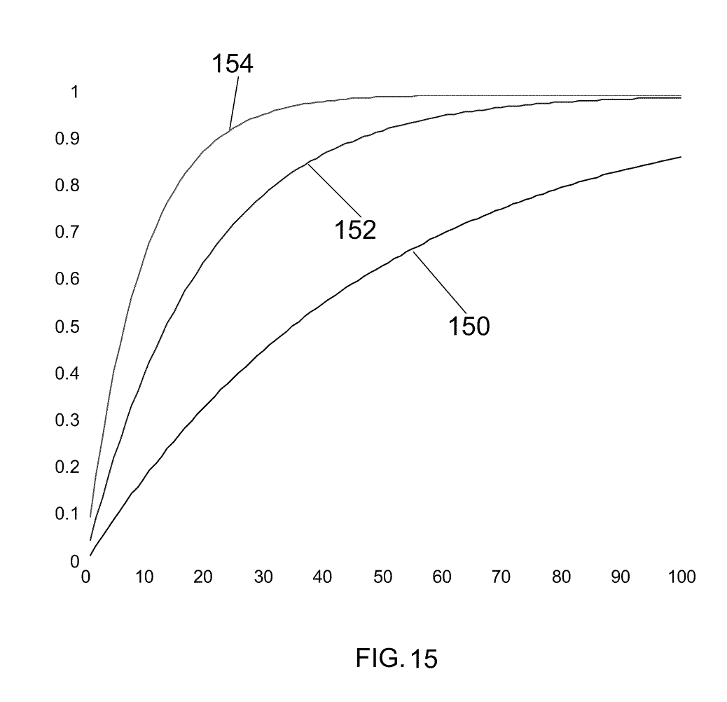

Reference is now made to FIG. 15 which shows three curves, 150, 152 and 154, each for a different sampling time. The probability of measuring extreme values, defined as different ρ values, as a function of sampling time is shown. Curve 150 shows the probability to measure the upper ρ=0.02, curve 152 is for ρ=0.05 and curve 154 for ρ=0.1.

The probability of measuring extreme values within a given N samples can be translated to continuous measurement T, if T=Ndt and dt≧1 sec to ensure a decorrelated signal. One can see from FIG. 15, that to measure at least values larger than 90% of all the possible values with a probability higher than 90%, it is enough to measure once for 22 sec.

One particular property of the above method is that independent variables can be collected on different occasions, allowing one to develop an algorithm that can learn and thus improve the statistical estimations over time. This approach, of course, assumes that the property of the source (antenna) does not be change between measurements. By comparing each new statistical set to the previous ones, changes in the statistics can be detected and then the antenna properties may be learnt again.

Given the results above, the proposed measurement strategy can be formulated. Since the same spot may be measured many times overall, it is possible to use a strategy that maximizes the probability to measure the characteristic statistics of the radiation field based on a steadily increasingly integrated amount of information. In other words, the more one measures a given spot the more one knows about the spot and the behaviour of the different frequencies at that spot.

Assuming a quasi-stationary signal, as has been noted, non-stationary trends are lower frequency only, so that added measurements taken at different occasions, say different days, tend to add to the statistical knowledge. And if the signal turns out to have low frequency fluctuations or it just changes in time, say due to non-periodic episodic type events such as weather or changes in the company setting, repeating the measurements is the best way to monitor it. In this case the average of the statistical properties measured repeatedly can be estimated, of course for a given spot and a given frequency.

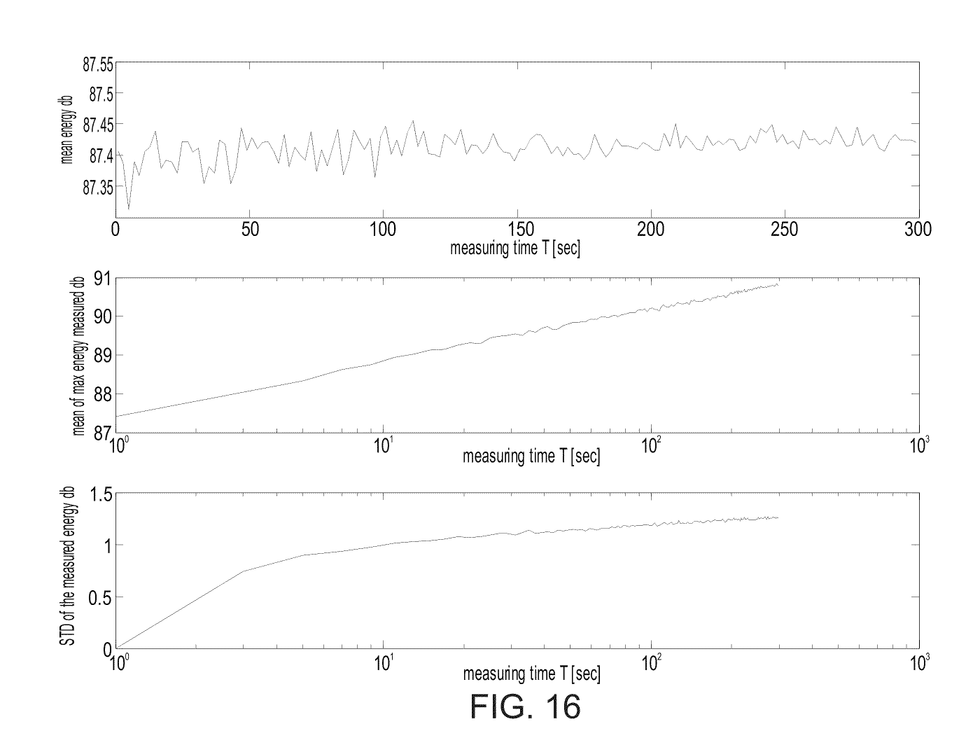

Reference is now made to FIG. 16, which shows the results of a Monte Carlo experiment. The experiment was designed such that an antenna time series was sampled randomly. The results of this experiment showed that the average measured statistical values depend logarithmically on the sampling time T. The mean of the maximum values MX, depends on the mean of the whole time series S and on the log(T).

mean(MX)=mean(sig)+a log(T), where the larger slope measured was a≈1.8. (3)

Eq-3 estimates the expected distance of the maximum from the mean that may be measured for a given sampling time. Similarly the mean measured σ can be estimated by:

mean(σ)=bₛ+aₛ log(T), where the larger slope measured was aₛ=0.12. (4)

In FIG. 16, the upper graph shows measured mean, the middle graph shows the maximum values and the lower graph shows standard deviation of an antenna with true average of 87.4 db and std of 1.28 db.

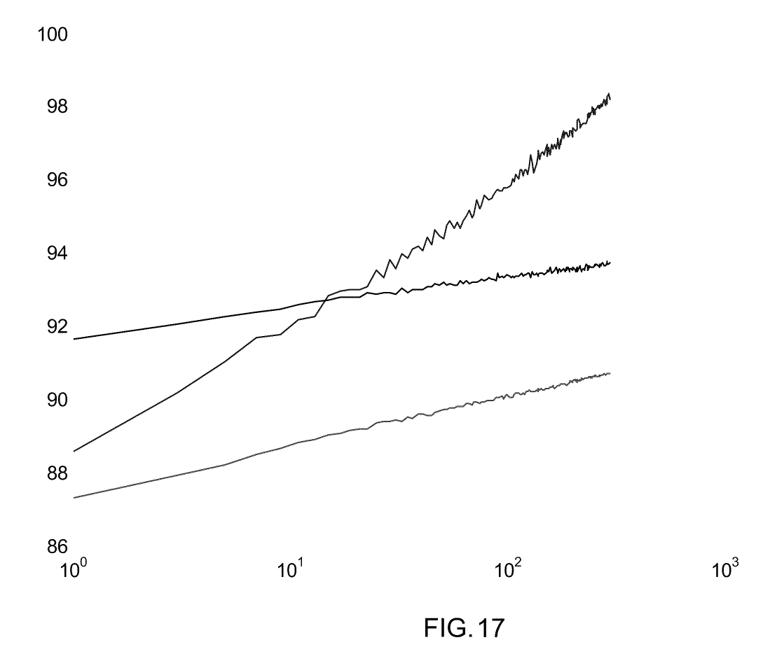

The results show that the measured mean fluctuates close to the total mean with changes of less then 1% even for a small sampling time. The logarithmic dependence of the maximum throughout the whole simulation suggests that rapid convergence toward the true max. It is also shown that, as expected, the standard deviation converges rapidly to the true value. Based on the simulation it shows that if one can assume a quasi-stationary signal, one can cluster (stack) different samples taken at different times of the same location to calculate the properties (slopes) of the regressions of the statistical variables. The robustness of the logarithmic dependants of the extreme can be seen in FIG. 17 which shows results for three different antennas or sources, and shows the differences in the slopes of the logarithmic dependence of the extreme values.

For a random variable one may never predict what would be the true ultimate extreme that the distribution will produce. In theory the distribution of such a truly random variable spans the whole real line [0 ∞]. However for any practical use, we can set a robust measurement strategy that will allow us the estimate the desired statistical moments (mean, standard deviation and max) properties and will allow us the estimate the convergence rate of the moments toward a threshold (say 95% of the values).

There is thus provided in accordance with some of the embodiments a single device that is a combined GPS device, a radiation detector, and a data logger, which may then be used with a mapping system.

In a further embodiment of the present invention there is provided a device which comprises a Personal Electro-Magnetic Adjustable and Discrete Radiation-Risk-Meter (PRRM).

The device described up to this point comprises a spectrum analyzer, which is a very expensive item of equipment, and thus precludes a version for personal use by private citizens. A spectrum analyzer however is needed as long as the general radiation pattern in the area is not known.

The PRRM does not include a spectrum analyzer and thus provides a device of suitable price for consumer use. Instead of analyzing spectrum the device makes use of the existing mapping to select a subset of bands found to be significant in the neighbourhood. The device then analyzes those bands alone.

The device may be updated, say via the Internet, as the radiation map for the area changes so that newly significant bands may be added and bands that cease to be significant may be dropped.

In greater detail, a device useful for consumers may be provided that does not include the spectrum analyzer.

The PRRM provides a low price but accurate electromagnetic radiation measurement tool.

The tool is designed for personal use to measure and assess the risk due to the load and variance of non ionizing electromagnetic radiation, in particular in the range of the cellular, electric power, radio and television antennas.

The method is based on predefining the relevant radiation bands per a given area (city, country) and plugging discrete and adjustable radiation measurements unit (RMU) per each relevant range.

The RMU may be tuned to a discrete frequency, and thus cheaply measure the radiation properties at a high sampling rate in order to capture small pulses of high radiation loading (PHRL). The overall risk assessment may be a function of the various key statistical properties of the radiation and not only of the average radiation loading over long time intervals as currently measured.

Here it is suggested that the variance and the rate in time of the PHRL may be as (or more) important than the average reading for human health.

Each RMU may sample the radiation around its frequency range and produce a radiation hazard statistical index (RHI) that weights the mean radiation loading, variance and PHRL. The RHI of all the RMU's may then be evaluated and displayed in a simple to grasp scale (say between 0 for no risk to 100 for very risky).

The user may then be able to measure the RHI in any relevant location.

A relevant location may be the place where one may spend significant amounts of time, such as bed, desk at place of work or study, desk at home, living-room etc.

An advanced model of the PRRM may include a module to log continuous measurements and to produce more detailed temporal statistical analysis such as diurnal changes and RHI distribution.

The terms “comprises”, “comprising”, “includes”, “including”, “having” and their conjugates mean “including but not limited to”. This term encompasses the terms “consisting of” and “consisting essentially of”.

As used herein, the singular form “a”, “an” and “the” include plural references unless the context clearly dictates otherwise.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention. To the extent that section headings are used, they should not be construed as necessarily limiting.

What is claimed is:

1. Apparatus for radiation mapping of a region comprising:
a spectrum analyzer for analyzing a local radiation field according to wavelength, and
a recording unit for recording the local radiation field at a given location provided by the spectrum analyzer.

2. Apparatus according to claim 1, wherein said recording unit is part of a positioning unit for obtaining a position reading to correlate with said recorded local radiation field, thereby to provide said radiation mapping.

3. Apparatus according to claim 2, further comprising a time correlation unit configured with time behavior of radiation fields, to correlate said analyzing according to wavelength with said time behavior, thereby to extrapolate a sample of said radiation field over a time period.

4. Apparatus according to claim 3, further comprising a superimposing unit configured to use said position reading for superimposing geographical information over said radiation mapping to produce an area map of said region including said radiation mapping.

5. Apparatus according to claim 4, further comprising an output selector for allowing a user to select between different frequencies, accumulated frequencies and times for showing in said area map.

6. The apparatus of claim 2, wherein said positioning unit comprises a global satellite-based positioning unit.

7. The apparatus of claim 6, configured to provide readings to a resolution of substantially three meters.

8. The apparatus of claim 1, wherein said spectrum analyzer is configured to include within said spectrum frequencies used in cellular telephony.

9. A method of mapping a region for local radiation levels, comprising:
moving through said region;
at locations in said region detecting and analyzing a spectrum of interest for radiation levels over said spectrum;
associating each location analysis with an indicator of said location;
associating each location analysis with a sampling time; and
using said location indicators, superimposing said analysis on a map of said region.

10. The method of claim 9, wherein said radiation levels are cellular radiation levels having repeat patterns over a time interval, the method comprising using said sampling times to correlate said local analyses with said repeat patterns to provide a time dimension to said analysis.

11. The method of claim 10, further comprising:
applying said analysis with a frequency dimension to said map, and
providing to said map an interface for allowing users to access said analysis according to said frequency dimension.

12. The method of claim 10, further comprising:
applying said analysis with said time dimension to said map, and to provide to said map an interface for allowing users to access said analysis according to said time dimension.

13. The method of claim 9, comprising selecting locations at a resolution of substantially three meters.

14. The method of claim 9, further comprising identifying a predetermined number of peak frequencies from said mapping at a location of interest to a consumer and providing said consumer with a detection device tuned for said regions of peak frequencies.

15. The method of claim 14, further comprising retuning said consumer detection device when said mapping indicates changes to said peak frequencies.

16. A method of mapping a radiation spectrum of interest to a region of interest, radiation levels in said spectrum obeying a periodicity, said periodicity defining a period, the method comprising:
obtaining samples at locations in said region at frequency intervals in said spectrum, each sample being obtained at a certain sample time,
for each frequency at said sample time, using said periodicity to extrapolate said sample to said period,
adding each of said extrapolated samples to a geographical map of said region of interest, as a series of layers on a time dimension, such as to provide a layer on said geographical map for each frequency time combination.

17. The method of claim 16, comprising providing an additional series of layers for cumulative radiation over said spectrum of interest.

18. The method of claim 16, further comprising providing a user interface for allowing a user to define one of said layers for display.
